(19) United States
(12) Patent Application Publication
(10) Pub. No.: US 2008/0310109 A1
(43) Pub. Date: Dec. 18, 2008

(54) Cooling structure for high voltage electrical parts of a hybrid electric vehicle

(75) Inventors: Nam-Seob Park, Gangseo-gu (KR); Yoshiro Shimoyama, Chiba (JP)

Correspondence Address: EDWARDS ANGELL PALMER & DODGE LLP, P.O. BOX 55874, BOSTON, MA, 02205, US

(73) Assignee: Hyundai Motor Company, Seoul (KR)

(21) Appl. No.: 11/980,224

(22) Filed: Oct. 30, 2007

(30) Foreign Application Priority Data
Jun. 18, 2007 (KR) 10-2007-0059258

(51) Int. Cl. H05K 7/20

(52) U.S. Cl. 361/697

(57) ABSTRACT

The present invention provides a cooling structure for high voltage electrical parts of a HEV in which a plurality of high voltage electrical parts are fixedly arranged in parallel on a cross section of a cooling passage in a case where the plurality of the high voltage electrical parts are cooled by air, thereby being able to supply cooling air at the same temperature to all electrical parts.

### CROSS-REFERENCE TO RELATED APPLICATION

This application claims under 35 U.S.C. §119(a) on Korean Patent Application No. 10-2007-0059258, filed on Jun. 18, 2007, the entire contents of which are incorporated herein by reference.

### BACKGROUND

(a) Technical Field

The present invention relates to a cooling structure for high voltage electrical parts of a hybrid electric vehicle (HEV). More particularly, the present invention relates to a cooling structure for high voltage electrical parts of a HEV in which a plurality of high voltage electrical parts are fixedly arranged in parallel on a cross section of a cooling passage, thus being able to supply cooling air at the same temperature to all the electrical parts.

(b) Background Art

Electrical systems of a vehicle include engine electrical systems, such as a starter system, an ignition system and a charging system, and lighting systems. However, as vehicles are more electronically controlled than before, most of their systems including a chassis electrical system have been computerized.

Various electrical parts, such as a lamp, an audio system, a heater, an air conditioner, etc., equipped in a vehicle receive power from a battery when the vehicle is stopped and from a generator when the vehicle is driven. Generally, a generation capacity of a 14V power system is used as a power voltage.

Recently, with the development of information technologies, various new technologies such as a motor-driven power steering, Internet, and the like have been applied to a vehicle in order to increase the convenience of using the vehicle. Moreover, it is expected that the development of new technologies to make the most of the existing vehicle systems will continue to progress.

A low voltage DC-DC converter 10 for supplying 12V electrical loads is installed in a hybrid electric vehicle (HEV) irrespective of soft or hard type.

In general, a DC-DC converter used as an alternator of a vehicle converts high voltage power into low voltage power to supply energy to the 12V electrical loads and charge a 12V battery.

Besides the DC-DC converter, the high voltage electrical parts include an inverter and an air conditioner inverter which convert DC voltage into AC voltage and supply the AC voltage to motors.

In connection with the cooling structure for the high voltage electrical parts, Japanese Patent Application Laid-open Publication No. 2004-025934 discloses a capacitor hybrid car in which capacitor units thereof are mounted in several layers on a side rail using loading brackets and apertures thereof are maintained to improve cooling performance.

Moreover, Japanese Patent Laid-open No. 2005-302698 discloses a battery pack equipped with a plurality of battery stacks including secondary cells is disposed in parallel in a case, a plurality of heat sinks between which the secondary cells are interposed, and the like, in which cooling air enters passages formed in the heat sinks, thus directly cooling the secondary cells of the battery pack.

U.S. Pat. No. 7,079,379 discloses a cooling structure for hybrid vehicle in which heat sinks of a PDU (an inverter) and a DC/DC converter are fixed to a projection of a frame and air flow apertures are disposed between the PDU and the DC/DC converter, thus allowing cooling air to flow therethrough.

U.S. Pat. No. 6,188,574 discloses a cooling structure for an electric vehicle in which cooling fins of a first electric component and cooling fins of a second electric component are disposed on an air passage and thus the electric components are cooled by the air flow.

Japanese Patent Application Laid-open Publication No. 2001-020737 discloses a cooling structure for high voltage electrical parts in which a cooling hole acting as a passage of cooling air is formed on the wall of a case of a heat sink 4 to cool high voltage electrical parts including a power unit 1 and a DC-DC converter 2, and the heat sink 4 is disposed between the high voltage electrical parts to blow cooling air to the high voltage electrical parts.

In FIGS. 1 to 3, reference numeral 3 denotes a cooling device, 5 denotes an air inlet, 6 denotes an air outlet, 7a denotes a first heat sink, 7b denotes a second heat sink, and 8 denotes a fan.

However, in the above structure, if the number of high voltage electrical parts is increased, the electrical parts should be disposed on the upstream or the downstream of a cooling air passage and the length of the cooling air passage between the upstream side and the downstream side will thus be required to increase, causing the cooling performance to be lowered in the downstream side by a difference in temperature of the cooling air.

As another installation method of high voltage electrical parts, FIG. 4 shows a structure in which a cooling hole is formed on the surface other than the opposing surfaces and respective units 21, 22 and 23 are disposed.

In FIG. 4, reference numeral 25 denotes a first heat sink, 26 denotes a second heat sink, and 23 denotes a third heat sink.

However, since the main body of the unit protrudes from a case 24 in three or four directions, it has a problem in that it is not proper to place the units in a limited space and it is difficult to utilize the space effectively.

The information disclosed in this Background section is only for enhancement of understanding of the background of the invention and should not be taken as an acknowledgement or any form of suggestion that this information forms the prior art that is already known to a person skilled in the art.

### SUMMARY OF THE INVENTION

The present invention has been made in an effort to solve the above problems, and an object of the present invention is to provide a cooling structure of high voltage electrical parts for a hybrid electric vehicle (HEV) that can reduce the length between an inlet and an outlet of cooling air and supply cooling air at the same temperature to all electrical parts.

In one aspect, the present invention provides a cooling structure for high voltage electrical parts of a hybrid electric vehicle in which a plurality of high voltage electrical parts are cooled by air, wherein a plurality of heat sinks are provided for cooling the plurality of high voltage electrical parts and are fixedly arranged in parallel on a cross section of a cooling passage through which cooling air flows.

Preferably, each of the plurality of heat sinks is provided for cooling each of the plurality of high voltage electrical parts.

In a preferred embodiment, the cooling passage is formed by the heat sinks and a planar bracket adhered to the lateral surface of the heat sinks for connecting the high voltage electrical parts.

In a further preferred embodiment, the planar bracket is formed by extending the length of a bracket along the high voltage electrical part or by arranging a plurality of brackets so as to be connected to the high voltage electrical parts.

Preferably, the planer bracket covers a lateral surface of the cooling passage along the shapes of the heat sinks and the cooling air of the cooling passages passes through the heat sinks.

### BRIEF DESCRIPTION OF THE DRAWINGS

FIGS. 1 to 3 are diagrams showing a prior art cooling structure for high voltage electrical parts of a vehicle;

FIG. 4 is a schematic diagram showing a state in which high voltage electrical parts are disposed in three directions in accordance with prior art;

FIG. 5 is a diagram illustrating a cooling structure for high voltage electrical parts in accordance with an exemplary embodiment of the present invention; and

FIG. 6 is a diagram illustrating a cooling structure in which a high voltage electrical part is added and disposed in parallel in accordance with another exemplary embodiment of the present invention.

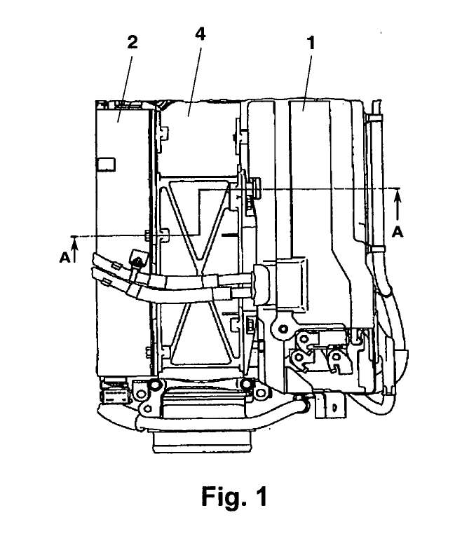

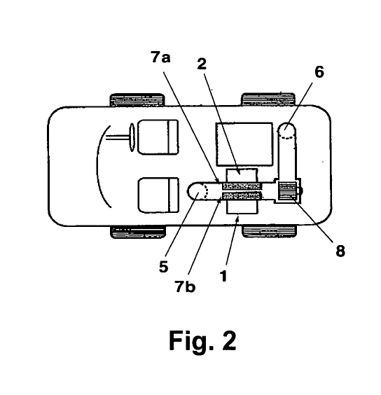

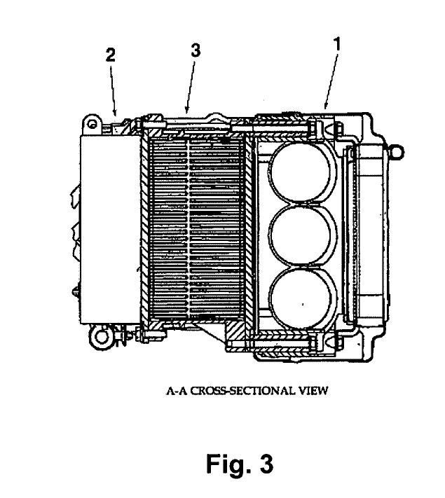

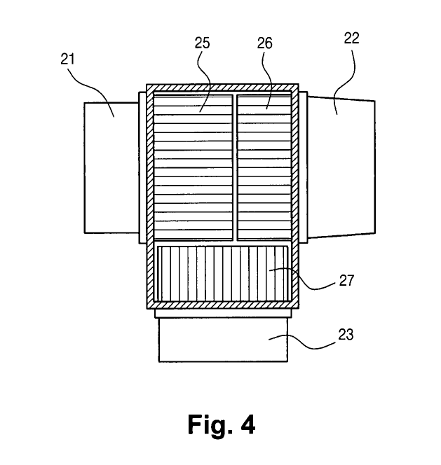

Reference numerals set forth in the Drawings includes reference to the following elements as further discussed below:

| | |
|---|---|
| 50: first heat sink | 51: second heat sink |
| 52: third heat sink | 53: inverter |
| 54: DC-DC converter | 55: air conditioner inverter |
| 56: first bracket | 57: second bracket |
| 58: first base | 59: second base |
| 60: third base | |

### DETAILED DESCRIPTION

Reference will now be made in detail to the preferred embodiment of the present invention, examples of which are illustrated in the drawings attached hereinafter, wherein like reference numerals refer to like elements throughout. The embodiments are described below so as to explain the present invention by referring to the figures.

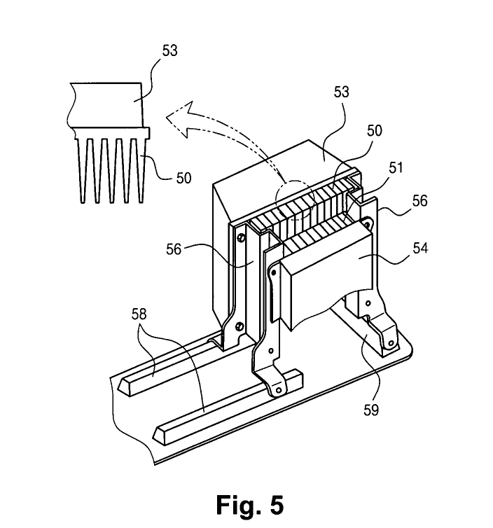

FIG. 5 is a diagram illustrating a cooling structure for high voltage electrical parts in accordance with an exemplary embodiment of the present invention.

In the cooling structure, heat sinks 50 and 51 are connected to electrical parts in parallel.

The high voltage electrical parts include, but are not limited to, an inverter 53, a DC-DC converter 54, and an air conditioner inverter 55, for example.

As shown in FIG. 5, the inverter 53 and the DC-DC converter 54 are disposed so as to face each other. A first heat sink 50 for cooling the inverter 53 and a second heat sink 51 for cooling the DC-DC converter 54 are disposed between the inverter 53 and the DC-DC converter 54. In this case, the cross sections of the first and second heat sinks 50 and 51 have projections in the form of comb teeth.

The inverter 53 and the DC-DC converter 54 may be connected to each other through a first bracket 56 by means of bolts. The first bracket 56 acts as a cooling passage for allowing cooling air to flow through the first heat sink 50 and the second heat sink 51.

That is, the first bracket 56 is closely adhered to both side surfaces of the first and second heat sinks 50 and 51, and the lower end portion of the first bracket 56 is fixedly connected to first bases 58 spaced from each other in a horizontal direction and to a second base 59 formed in a vertical direction.

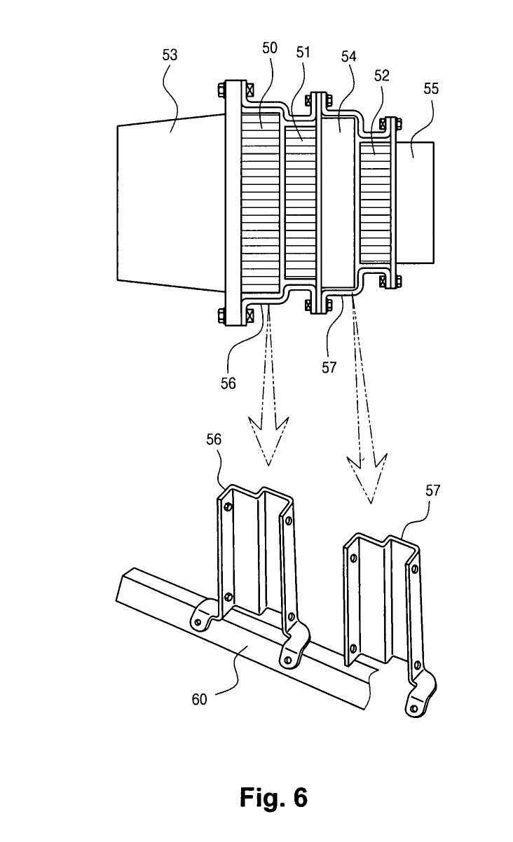

FIG. 6 is a diagram illustrating a cooling structure in which a high voltage electrical part is added and disposed in parallel on the above-described structure. That is, in the cooling structure of FIG. 6, the air conditioner inverter 55 is further provided to the cooling structure of FIG. 5 and a third heat sink 52 for cooling the air conditioner inverter 55 is further disposed.

The DC-DC converter 54, the third heat sink 52 and the air conditioner inverter 55 may be connected to one another by a second bracket 57. The second bracket 57 is closely adhered to both side surfaces of the DC-DC converter 54 and the third heat sink 52, and the lower end portion of the second bracket 57 is fixedly connected to a third base 60.

In accordance with the embodiments of the present invention, since all high voltage electrical parts are fixedly arranged in parallel on a cross section of a cooling passage as shown in FIG. 5, the length of the cooling passage between a cooling air inlet and a cooling air outlet may not be long, thus supplying cooling air at the same temperature to all electrical parts.

Moreover, since the cooling passage is formed in a box shape in combination of the base members 58 and 59 and the planar brackets 56 and 57 connected to the heat sinks 50 to 52 for the respective high voltage electrical parts, it is unnecessary to form a separate box-shaped passage for the cooling air flow therein.

Furthermore, it is possible to install any additional high voltage electrical parts in parallel by extending the length of the bracket or by adding at least one further bracket, such as the second bracket 57 as shown in FIG. 6.

Lastly, the cooling air passage can be formed so as to comply with the shapes of the heat sinks for the respective high voltage electrical parts by modifying (bending) the shapes of the brackets 56 and 57. Accordingly, an unnecessary space is not created in the vicinity of the heat sinks 50 to 52, and all cooling air passes through the heat sinks 50 to 52, thus improving the cooling efficiency.

In accordance with the embodiments of the present invention, parts cost can be reduced significantly, including tooling cost, material cost, processing cost and management.

As describe above, the cooling structure for high voltage electrical parts of a hybrid electric vehicle in accordance with the present invention provides advantages including the following:

1) A plurality of high voltage electrical parts are fixedly arranged in parallel on a cross section of a cooling passage in a case where the plurality of the high voltage electrical parts is cooled by air, thus being able to supply cooling air at the same temperature to all electrical parts;

2) Since the cooling passage is formed in a box shape in combination of the base members and the planar brackets connected to the heat sinks for the respective high voltage electrical parts, it is unnecessary to form a separate box-shaped passage for the cooling air flow therein, thus reducing the parts cost;

3) It is possible to install any additional high voltage electrical parts in parallel by extending the length of the bracket or by adding a further bracket; and

4) Since the cooling air passage can be formed so as to comply with the shapes of the heat sinks for the respective high voltage electrical parts by modifying (bending) the shapes of the brackets, an unnecessary space is not created in the vicinity of the heat sinks, and all cooling air of the cooling passages passes through the heat sinks, thus improving the cooling efficiency.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A cooling structure for high voltage electrical parts of a hybrid electric vehicle in which a plurality of high voltage electrical parts are cooled by air, wherein a plurality of heat sinks are provided for cooling the plurality of high voltage electrical parts and are fixedly arranged in parallel on a cross section of a cooling passage through which cooling air flows.

2. The cooling structure of claim 1, where each of the plurality of heat sinks is provided for cooling each of the plurality of high voltage electrical parts.

3. The cooling structure of claim 1, wherein the cooling passage is formed by the heat sinks and a planar bracket adhered to the lateral surface of the heat sinks for connecting the high voltage electrical parts.

4. The cooling structure of claim 3, wherein the planar bracket is formed by extending the length of a bracket along the high voltage electrical part or by arranging a plurality of brackets so as to be connected to the high voltage electrical parts.

5. The cooling structure of claim 4, wherein the planer bracket covers a lateral surface of the cooling passage along the shapes of the heat sinks and the cooling air of the cooling passages passes through the heat sinks.
